(19) United States
(12) Patent Application Publication
(10) Pub. No.: US 2007/0056158 A1
(43) Pub. Date: Mar. 15, 2007

(54) Method for manufacturing second-generation superconducting wire for transposition and superconducting coil manufactured using the same

(76) Inventors: Hee Gyoun Lee, Uiwang-si (KR); Gye Won Hong, Seongnam-si (KR); Kyeong Dal Choi, Seoul (KR); Woo Seok Kim, Seoul (KR); Seung Wook Lee, Ansan-si (KR)

Correspondence Address: CANTOR COLBURN, LLP, 55 GRIFFIN ROAD SOUTH, BLOOMFIELD, CT, 06002, US

(21) Appl. No.: 11/487,664

(22) Filed: Jul. 17, 2006

(30) Foreign Application Priority Data
Sep. 12, 2005 (KR) 10-2005-84817

(51) Int. Cl. H01L 39/24

(52) U.S. Cl. 29/599; 29/868; 29/605

(57) ABSTRACT

A method for performing transposition of second-generation superconducting wires, and a superconducting coil manufactured using the same are disclosed. The method for manufacturing a second-generation superconducting wire comprises: slitting a multiple-layered thin superconducting wire film, obtained by epitaxial growth, to form a zigzag-shaped slit portion which includes a plurality of sections each having a predetermined first length and a bent portion having a predetermined second length; continuously and repeatedly processing each section of the slit portion of the superconducting wire film until a desired length is processed to obtain first and second wires using two superconducting wire films; positioning the first and second wires so their bent portions face each other; and interweaving the first and second wires together so the first wire passes over the second wire at their first overlapped portion and below the second wire at their second overlapped portion, to couple the first and second wires.

### BACKGROUND OF THE INVENTION

1. Field of the Invention

The present invention relates to a second-generation superconducting coil, and more particularly, to a method for performing transposition of second-generation superconducting wires, and a superconducting coil manufactured using the same.

2. Description of the Related Art

Generally, certain materials have no resistance below a certain temperature. When using these materials, electric current can flow therethrough without generation of heat, and therefore, these materials result in no energy loss. Such a kind of material is called a superconductor. As well known in the art, superconducting phenomenon arises in specific materials, and is affected by certain conditions, such as for example, temperature, magnetic field, and conduction current.

The superconductor allows the flow of electric current therethrough without resistance only below a transition temperature Tc and under a critical magnetic field Hc. In this case, the maximum conduction current that is able to flow through the superconductor without resistance is a critical electric current density Jc. For various applications thereof, it is advantageous for the superconductor to be processed to have a line or tape shape. Recently, the processed superconductor has been widely used in superconducting electromagnets for generating a high-strength magnetic field.

As an application example of the superconductor, a coil is manufactured by winding a wire based on a variety of geometrical shapes. If electric current is applied through the wire, the coil generates a magnetic field. In particular, if the wire is a superconductor, the coil has no loss of electricity due to a resistance, and is called as a superconducting coil.

The superconducting coil or winding is generally used in a transformer, motor, and spectroscopy of magnetic resonance imaging (MRI) and nuclear magnetic resonance (NMR). When the superconducting coil is manufactured by overlapping a plurality of superconducting wires one above another, first of all, transposition is important in the superconducting coil or winding since it can balance impedances of the respective wires, resulting in an increase in a critical electric current of the overall wires as well as a reduction in the loss of alternating current.

Considering a currently used method for obtaining first-generation superconducting wires for use in the manufacture of the superconducting coil, first, BSCCO-based superconductor is pulverized into fine powder, and then, the superconducting powder is charged into silver tubes. After that, by performing a plurality of extrusion molding processes, first-generation superconducting wires having a multiple-core tape shape are obtained. Transposition of the plurality of first-generation superconducting wires, however, has several problems in that production efficiency deteriorates due to a complicated process, and also, there is no standardized transposition distance. A current known example of transposition using the first-generation superconducting wires includes a Roebel bar, which is developed by Simens of Germany. Most of other examples are adapted to realize transposition at electric current introduction terminals after completing the manufacture of a superconducting coil. Meanwhile, in the case of second-generation superconducting wires for replacing the first-generation superconducting wires, they are manufactured by depositing a superconducting layer on a nickel alloy substrate, and therefore, it is difficult to perform transposition in the same manner as the Roebel bar. Furthermore, it is difficult to realize transposition at electric current introduction terminals when a great number of coils are used. Another problem is in that it is impossible to fully develop advantages of the superconducting wires since heat generated from the electric current introduction terminals results in generation of loss.

### SUMMARY OF THE INVENTION

Therefore, the present invention has been made in view of the above problems, and it is an object of the present invention to provide a method for manufacturing superconducting wires wherein a plurality of second-generation superconducting wires are processed based on a pitch required for transposition thereof and the processed superconducting wires are interwoven together to balance impedances of the respective wires in a simplified manner, whereby a critical electric current of the overall wires can be increased and the loss of alternating current can be reduced, and to provide a superconducting coil manufactured using the same.

To achieve the transposition of the superconducting wires, it is important to regulate a transposition pitch distance to be less than 20 cm. In the case of the second-generation superconducting wires that have been recently in the spotlight, they are first formed to have a thin film shape, and then, are slit into line shaped superconducting wires each having a certain width. During the implementation of the slitting process, preferably, the superconducting wires are slit to have a zigzag shape in consideration of a pitch. In succession, the plurality of resulting zigzag-shaped wires are interwoven together. This has the preferable effects of balancing impedances of the respective superconducting wires, increasing a critical electric current, and reducing loss of alternating current.

In accordance with one aspect of the present invention, the above and other objects can be accomplished by the provision of a method for manufacturing second-generation superconducting wires comprising: slitting a multiple-layered thin superconducting wire film, which is obtained via an epitaxial growth, to form a zigzag-shaped slit portion, the slit portion including a plurality of sections each having a predetermined first length, and each section being provided with a bent portion having a predetermined second length; continuously and repeatedly processing the slit portion of the superconducting wire film on the basis of each section until a desired length thereof is processed, to obtain first and second wires by use of two superconducting wire films; positioning the first and second wires such that their bent portions face each other; and interweaving both the first and second wires together such that the first wire passes over the second wire at their first overlapped portion, and then, passes below the second wire at their second overlapped portion, to couple the first and second wires with each other.

Preferably, a width of the slit portion of the superconducting wire film may be adjusted to form a single wire or a plurality of wires.

Preferably, the predetermined second length of the bent portion may be adjustable within a range of the predetermined first length.

Preferably, each of the processed first and second wires may be formed by interweaving a plurality of wires together in a regular manner or optionally selected manner.

Preferably, the superconducting wire film may be processed by use of a method selected from among a method using shear force of slitters and a method using electrical discharge of wires.

In accordance with another aspect of the present invention, the above and other objects can be accomplished by the provision of a superconducting coil manufactured by using second-generation superconducting wires, wherein first and second wires, each obtained by processing a superconducting wire film to have a zigzag shape and including a single wire or a plurality of wires, are interwoven together on the basis of their first and second overlapped portions, to have a tape shape in their coupled state, and the coupled first and second wires are spirally wound on a bobbin to form a superconducting coil.

### BRIEF DESCRIPTION OF THE DRAWINGS

The above and other objects, features and other advantages of the present invention will be more clearly understood from the following detailed description taken in conjunction with the accompanying drawings, in which:

FIGS. 1A to 1C are views illustrating sequential processes of a method for manufacturing a second-generation superconducting wire in accordance with a first embodiment of the present invention;

FIGS. 2 and 3 are views illustrating a second-generation superconducting wire in accordance with a second embodiment of the present invention;

FIG. 4 is a view illustrating a second-generation superconducting wire in accordance with a third embodiment of the present invention;

FIG. 5 is a perspective view illustrating a superconducting coil in accordance with the present invention;

FIGS. 6A and 6B are views illustrating a method for processing a superconducting wire film using shear force in accordance with the present invention;

FIGS. 7A and 7B are views illustrating a method for processing a superconducting wire film using electrical discharge of wires in accordance with the present invention; and

FIG. 8 is a flow process chart of a second-generation superconducting wire in accordance with the present invention.

### DESCRIPTION OF THE PREFERRED EMBODIMENTS

Now, constituent elements of the present invention will be explained with reference to the accompanying drawings.

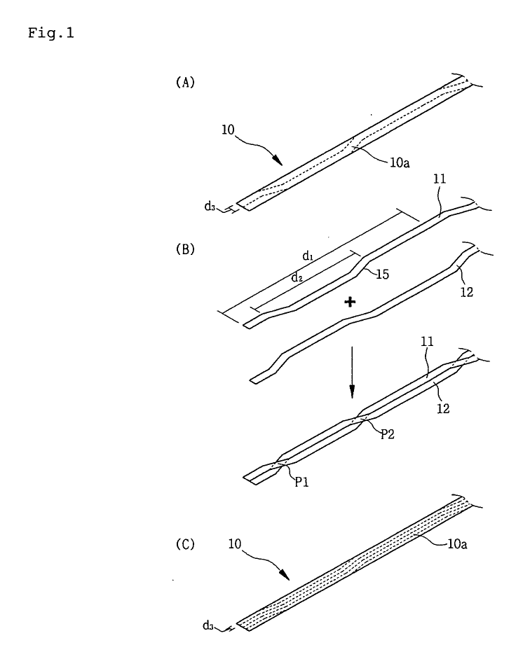

FIGS. 1A to 1C illustrate a method for manufacturing a second-generation superconducting wire. Referring first to FIG. 1A illustrating a superconducting wire film 10 to be processed, the superconducting wire film 10 is slit to remain a zigzag-shaped slit portion 10a having a predetermined width d3. The zigzag-shaped slit portion 10a of the superconducting wire film 10 includes a plurality of sections each having a predetermined first length d1. As shown in FIG. 1B, each section having the predetermined first length d1 is provided with a bent portion 15 having a predetermined second length d2. On the basis of each section having the predetermined first length d1, the slit portion 10a of the superconducting wire film 10 is continuously and repeatedly processed until a desired length thereof is completely processed, to obtain a first superconducting wire 11. In succession, a second superconducting wire 12 is manufactured in the same manner as the first superconducting wire 11. To be coupled with the first wire 11, first, the second wire 12 is rotated by an angle of 180° such that the bent portions 15 of both the first and second wires 11 and 12 face each other. After that, the first and second wires 11 and 12 are interwoven together such that the first wire 11 passes over the second wire 12 at their first overlapped portion P1, and then, passes below the second wire 12 at their second overlapped portion P2.

The reason why forming the superconducting wire film 10 with the zigzag-shaped slit portion 10a is to reduce the loss of alternating current that is generated in superconducting wires. The loss of alternating current is extremely harmful since the greater the loss of alternating current, the greater cooling load for the superconducting wires.

The width d3 of the slit portion 10a of the superconducting wire film 10 is adjustable such that the superconducting wire film 10 is used to form a single wire as shown in FIG. 1A or a plurality of wires as shown in FIG. 1C. For example, if a width of the superconducting wire film 10 is 1 cm and the width d3 of the slit portion 10a to be processed is 5 mm, only a single wire can be obtained. However, if the width d3 of the slit portion 10a to be processed is 1 mm, nine wires can be obtained. In conclusion, when using superconducting wire films having the same width as each other, the smaller the width d3 of the slit portion 10a to be processed, the greater the number of wires obtained.

Also, it should be noted that the bent portion 15 having the predetermined second length d2 is adjustable in length within a range of the predetermined first length d1 of each section.

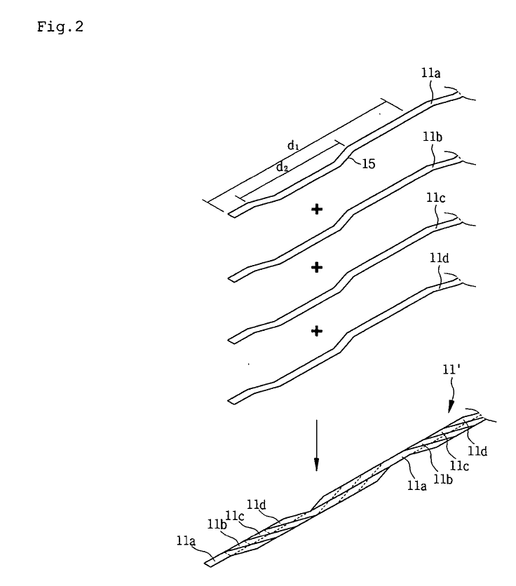

FIGS. 2 to 4 illustrate different second-generation superconducting wires in accordance with second and third embodiments of the present invention. These embodiments of the present invention propose a method for manufacturing a second-generation superconductor using a plurality of superconducting wires, which is suitable for use in an electricity transformer that requires an electric current of 1000 to 2000 Amp or a large-scale ship motor that requires an electric current of more than 2000 Amp.

Referring to FIG. 2, a plurality of wires 11a, 11b, 11c, and 11c, which have the same shape as the first wire 11 of FIG. 1, are prepared. In the present embodiment, on the basis of a first wire 11a, a second wire 11b is attached to a lower surface of the first wire 11a such that they are interwoven together about their overlapped portions P1 and P2. Similarly, a third wire 11c is attached to a lower surface of the second wire 11b such that they are interwoven together about their overlapped portions P1 and P2. Finally, a fourth wire 11d is attached to a lower surface of the third wire 11c such that they are interwoven together about their overlapped portions P1 and P2. In this way, all the wires 11a, 11b, 11c, and 11d form a first wire 11′. Here, the interweaving order of the wires 11a, 11b, 11c, and 11d may be regular or be optionally determined, and also, the number of wires can be selectively determined as occasion demands.

Referring to FIG. 3, in addition to the first wire 11′, formed by interweaving the plurality of wires 11a, 11b, 11c, and 11d together, a second wire 12′ is formed in the same manner as the first wire 11′ by interweaving a plurality of wires 12a, 12b, 12c, and 12d together. To be coupled with the first wire 11′, first, the second wire 12′ is rotated by an angle of 180° such that the first and second wires 11′ and 12′ face each other. In this case, in the same manner as shown in FIG. 1B illustrating the coupling between the first and second wires 11 and 12, the first wire 11′, which consists of the plurality of wires, passes over the second wire 12′, which consists of the plurality of wires, at their first overlapped portion P1, and then, passes below the second wire 12′ at their second overlapped portion P2.

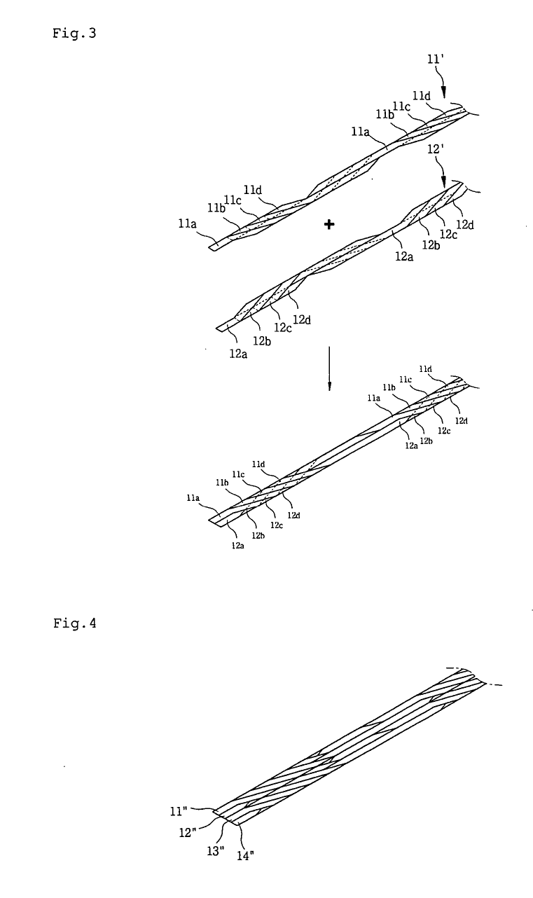

Referring to FIG. 4, each of first to fourth wires 11″, 12″, 13″, and 14″ is prepared by interweaving five superconducting wires together in the same manner as shown in FIG. 2. To couple the first to fourth wires 11″ to 14″ with one another, first, the second wire 12″ is rotated by an angle of 180° as shown in FIG. 3, such that both the first and second wires 11″ and 12″ are interwoven together. In the present embodiment, as will be easily understood, the interwoven first and second wires 11″ and 12″ form a bundle of ten superconducting wires. After the coupling of both the first and second wires 11″ and 12″, repeatedly, each of third and fourth wires 13″ and 14″ is formed by interweaving five superconducting wires together, and then, the third and fourth wires 13″ and 14″ are interwoven together. Similarly, the interwoven third and fourth wires 13″ and 14″ form a bundle of ten superconducting wires. Accordingly, if the interwoven third and fourth wires 13″ and 14″ are attached to a side of the interwoven first and second wires 11″ and 12″, a pair of wire bundles each consisting of ten superconducting wires (totally, consisting of twenty superconducting wires) are arranged in two rows. Here, it should be understood that another pair of wire bundles each consisting of ten superconducting wires (totally, consisting of twenty superconducting wires) may be attached to the above described superconducting wires, whereby a desired rows of wire bundles can be obtained without a limit in number.

Accordingly, if a single superconducting wire has an electric current capacity of 100 Amp, the resulting superconducting wires, which include twenty superconducting wires, have an electric current capacity of 2000 Amp, and therefore, are able to be used in a large-capacity apparatus.

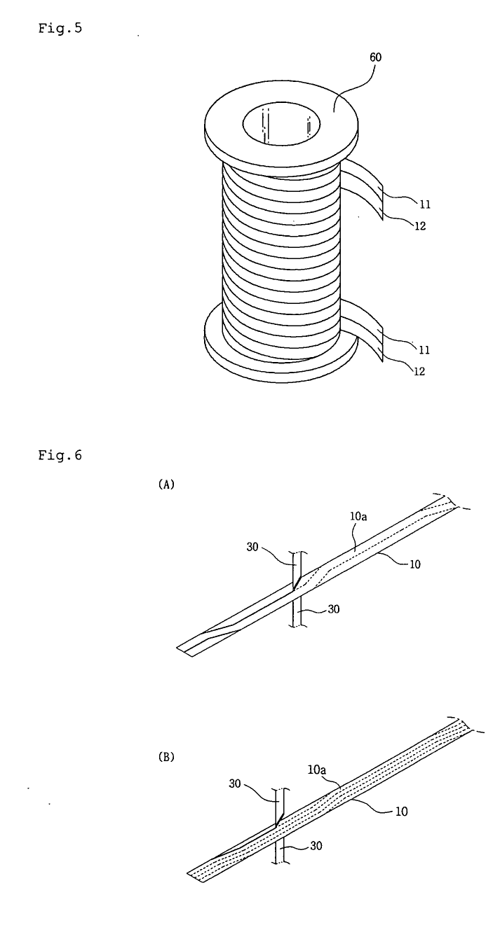

FIG. 5 is a perspective view illustrating a superconducting coil 20 using the superconducting wires processed as stated above. The superconducting coil 20 is spirally wound on a bobbin 60 starting from a lower end of the bobbin 60 such that a distal end of the coil 20 protrudes from an upper end of the bobbin 60. When in use, electric current is applied to both ends of the superconducting coil 20 wound on the bobbin 60.

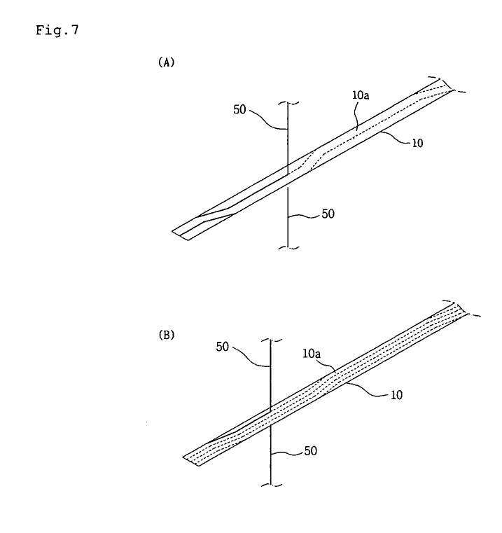

Meanwhile, a method for processing the superconducting wire film 10 may be selected from among a processing method using shear force of slitters 30 provided at upper and lower sides of the superconducting wire film 10 as shown in FIGS. 6A and 6B, and a processing method using the electrical discharge of wires 50 provided at upper and lower sides of the superconducting wire film 10 as shown in FIGS. 7A and 7B. FIGS. 6A and 7A illustrate the processing of a single wire, and FIGS. 6B and 7B illustrate the processing of a plurality of wires.

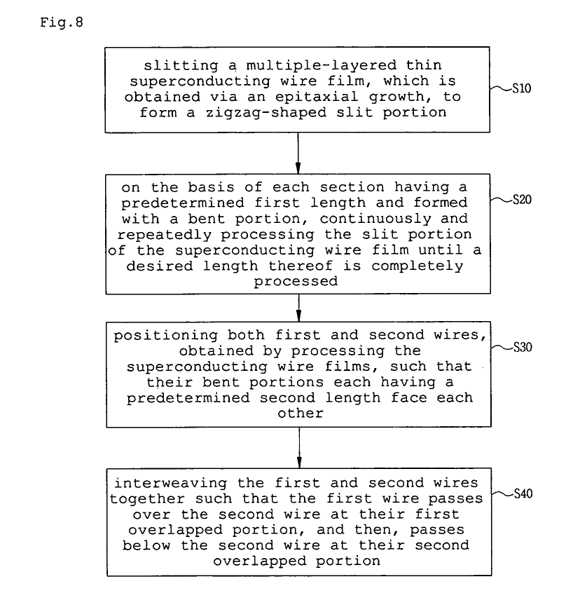

FIG. 8 illustrates a flow process chart of coated high-temperature superconducting wires. First, a multiple-layered thin superconducting wire film 10, which is obtained via an epitaxial growth, is slit to form the zigzag-shaped slit portion 10a (S10). As stated above, the zigzag-shaped slit portion 10a of the superconducting wire film 10 includes the plurality of sections each having the predetermined first length d1, and each section is provided with the bent portion 15 having the predetermined second length d2. Accordingly, on the basis of each section having the predetermined first length d1, the slit portion 10a of the superconducting wire film 10 is continuously and repeatedly processed until a desired length thereof is completely processed (S20). Then, if the first and second wires 11 and 12 are obtained via the above-described method, the first and second wires 11 and 12 are positioned such that their bent portions 15 face each other (S30). Finally, the first and second wires 11 and 12 are interwoven together such that the first wire 11 passes over the second wire 12 at their first overlapped portion P1, and then, passes below the second wire 12 at their second overlapped portion P2 (S40).

The interwoven first and second wires 11 and 12, manufactured as stated above, have a tape shape, and the resulting tape is wound on the bobbin 60 to form the superconducting coil 20. In the present invention, the multiple-layered superconducting wire film 10, obtained via an epitaxial growth, may be manufactured as an insulator or conductor in accordance with use purpose thereof. The superconducting coil 20 of the present invention, which is obtained by lapping and winding, is suitable for use in transformers, motors, and spectroscopy of magnetic resonance imagining (MRI) and nuclear magnetic resonance (NMR).

As apparent from the above description, the present invention provides a method for manufacturing superconducting wires wherein a plurality of superconducting wires are interwoven together, whereby impedances of the respective superconducting wires can be balanced, a critical electric current of the overall wires can increase, and the loss of alternating current can decrease. Further, in accordance with the present invention, there is no limit in the number and length of wires, and a distance between bent portions of each wire can be freely adjusted as occasion demands. This results in an improvement in productivity by virtue of standardization of superconducting wires.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method for manufacturing second-generation superconducting wires comprising:
slitting a multiple-layered thin superconducting wire film, which is obtained via an epitaxial growth, to form a zigzag-shaped slit portion, the slit portion including a plurality of sections each having a predetermined first length, and each section being provided with a bent portion having a predetermined second length;
continuously and repeatedly processing the slit portion of the superconducting wire film on the basis of each section until a desired length thereof is processed, to obtain first and second wires by use of two superconducting wire films;
positioning the first and second wires such that their bent portions face each other; and
interweaving both the first and second wires together such that the first wire passes over the second wire at their first overlapped portion, and then, passes below the second wire at their second overlapped portion, to couple the first and second wires with each other.

2. The method as set forth in claim 1, wherein a width of the slit portion of the superconducting wire film is adjusted to form a single wire or a plurality of wires.

3. The method as set forth in claim 1, wherein the predetermined second length of the bent portion is adjustable within a range of the predetermined first length.

4. The method as set forth in claim 1, wherein each of the processed first and second wires is formed by interweaving a plurality of wires together in a regular manner or optionally selected manner.

5. The method as set forth in claim 1, wherein the superconducting wire film is processed by use of a method selected from among a method using shear force of slitters and a method using electrical discharge of wires.

6. A superconducting coil manufactured by using second-generation superconducting wires, wherein first and second wires, each obtained by processing a superconducting wire film to have a zigzag shape and including a single wire or a plurality of wires, are interwoven together on the basis of their first and second overlapped portions, to have a tape shape in their coupled state, and the coupled first and second wires are spirally wound on a bobbin to form a superconducting coil.
